(19) United States
(12) Patent Application Publication
(10) Pub. No.: US 2023/0299249 A1
(43) Pub. Date: Sep. 21, 2023

(54) LED LIGHT BOARD AND MANUFACTURING METHOD THEREOF

(71) Applicant: ShenZhen YunMiXin Display Technology Co., Ltd, Shenzhen (CN)

(72) Inventors: Chong Xiong, Shenzhen (CN); Chang’ao Liu, Shenzhen (CN)

(21) Appl. No.: 18/319,478

(22) Filed: May 18, 2023

(30) Foreign Application Priority Data
Sep. 2, 2022 (CN) 202211075988.9

(51) Int. Cl. H01L 33/60; H01L 25/075; H01L 33/56

(52) U.S. Cl. CPC H01L 33/60; H01L 25/0753; H01L 33/56; H01L 2933/0058; H01L 2933/005

(57) ABSTRACT

An LED light board includes a light board body, a fixing part and an adhesive layer. A surface of the light board body is provided with a plurality of LED light-emitting chips at intervals, and a region of the surface of the light board body without the LED light-emitting chips configured is provided with a first reflecting layer. A bottom side of the fixing part is provided with a plurality of grooves, and a region of the bottom side without the grooves configured is provided with a second reflecting layer. The adhesive layer is fixedly connected with the light board body by the adhesive layer, the fixing part is located above the light board body, and each of the LED light-emitting chips are matched with each of the grooves. The present application improves the reflectivity of the LED light board, and avoids the defects of time-consuming dispensing process.

### FIELD OF THE INVENTION

The present application relates to the technical field of liquid crystal display, in particular to an LED light board and a manufacturing method thereof.

### BACKGROUND OF THE INVENTION

A liquid crystal display (LCD) requires a backlight system to provide a uniform surface light source, and currently the common scheme in the backlight system is to place multiple LED (light emitting diode) light sources and lens at the bottom, and then place a diffusion sheet at the height of h, to turn the light from multiple LED light sources into a uniform surface light source. With the development of LCD technology, in order to pursue compact and thin size and dynamic backlight technology, a mini-LED technology has appeared in recent years. FIG. 1 shows an LCD system with mini-LED technology, which includes a mini-LED light board 11, a diffusion sheet 12, a quantum dot film 13, an optical film 14 and a liquid crystal module 15 successively arranged above the back cover 10, and multiple LED light-emitting chips 16 arranged in a dot matrix are configured o the mini-LED light board. In this system, the LED light-emitting chip 16 is a blue LED with small size, usually between 100 and 500 microns. There are thousands of blue LED light-emitting chips 16 on the mini-LED light board 11. The diffusion sheet 12 is configured at a certain distance from the mini-LED light board 11, which is configured to convert the dot-matrix blue light emitted by thousands of LED light-emitting chips 16 into a uniform surface light source.

In this optical system, a large amount of light will be reflected to the surface of the mini-LED light board. In order to utilize the light, a layer of white reflective ink 17 with reflectivity of about 85% (specific structure is shown in FIG. 2) is usually coated on the surface of the mini-LED light board 11. In order to further improve the reflectivity, a reflective sheet 18 with holes may be attached to the surface of the reflective ink 17, which has a reflectivity up to 95%. However, since thousands of LED light-emitting chips 16 are formed on the surface of mini-LED light board 11, it's necessary to configure windows or holes on the reflective ink 17 and the reflective sheet 18, which leads to the following defects. First, the reflective sheet is usually made of polymer PET material, which has the problem of absorbing water and expanding and shrinking after high temperature. In view of this, relative large holes opened on the reflective sheet are required, so as to avoid the shrinking of the reflective sheet to damage the LED light-emitting chips. Further in view of the limitation of the hole forming process, such holes usually have a diameter of more than 2 mm, which is considered as large size. Therefore, in the situation that the spacing between LED light-emitting chips is less than 3 mm, it would be unbeneficial to use the reflective sheet. At this time, in order to improve the reflectivity of the mini-LED light board, it has to increase the reflectivity of the white ink, such that, the white ink on the light board must be reflow welding (under temperature up to 260° C.) with the mini-LED light board. Unfortunately, the material characteristics of the white ink will change at high temperature, such as the reflectivity will be decreased, and color difference will be generated. By these tokens, it's a challenge to improve the reflectivity of the panel under the situation of LED spacing less than 3 mm. Second, under the situation of LED spacing less than 3 mm, the number of LED light-emitting chips usually is up to tens of thousands. For protecting the LED light-emitting chips, it's necessary to dispense protection glue 19 on the LED light-emitting chips one by one, which however requires quite long process time by using one-by-one dispensing process, and brings cost and yield problems by using other process such as silicone molding on surface level.

### SUMMARY OF THE INVENTION

A first purpose of the present invention is to provide an LED light board, which improves the reflectivity of the LED light board, and avoids the defects of time-consuming dispensing process.

A second purpose of the present invention is to provide a manufacturing method of an LED light board.

To achieve the above purposes, as a first aspect, the present invention provides an LED light board including a light board body, a fixing part and an adhesive layer. Specifically, a surface of the light board body is provided with a plurality of LED light-emitting chips at intervals, a region of the surface of the light board body without the LED light-emitting chips configured is provided with a first reflecting layer; the fixing part is transparent and has a bottom side faced towards the light board body, the bottom side is provided with a plurality of grooves corresponding to each of the LED light-emitting chips, a region of the bottom side of the fixing part without the grooves configured is provided with a second reflecting layer; and the adhesive layer is transparent, the fixing part is fixedly connected with the light board body by the adhesive layer, the fixing part is located above the light board body, and each of the LED light-emitting chips are matched with each of the grooves.

Preferably, the LED light-emitting chips arranged in a dot matrix are configured on the surface of the light board body.

Preferably, the first reflecting layer and the second reflecting layer include reflective inks.

Preferably, the fixing part is made of glass material or polymer optical material.

Preferably, the polymer optical material is selected from at least one of PMMA, PS and PET.

Preferably, the adhesive layer includes silicone material or UV adhesive.

Accordingly, as a second aspect, the present invention further provides a manufacturing method of an LED light board, including the following steps:
(1) providing a fixing part, wherein a side of the fixing part is provided with a plurality of grooves, a region of the side of the fixing part without the grooves configured is provided with a second reflecting layer;
(2) providing an adhesive layer in the grooves and on a surface of the second reflecting layer;
(3) providing a light board body, wherein a surface of the light board body is provided with a plurality of LED light-emitting chips at intervals, a region of the surface of the light board body without the LED light-emitting chips configured is provided with a first reflecting layer, and the first reflecting layer is coating a hot melt adhesive;
(4) fitting the fixing part on the light board body, so that each of the grooves corresponds to each of the LED light-emitting chips;
(5) heating and melting the hot melt adhesive, and pressing the fixing part to the light board body under an action of gravity; and
(6) placing in an oven and curing the adhesive layer to obtain an LED light board.

The beneficial effects of the invention follow.

First, in the present invention, the region of the bottom side of the fixing part without the grooves configured is provided with a second reflecting layer, as the second reflecting layer will not go through reflow welding process with the LED light chips, therefore there is no reflectivity loss on the second reflecting layer, which greatly improves the reflectivity of the panel.

Second, the fixing part of the present invention is provided with grooves, the fixing part is preferably made of glass material, and the grooves configured on the fixing part may be formed by chemical etching, which facilitates to reduce the diameter of grooves, in such a way, the area of the first reflecting layer and the second reflecting layer can be increased, thereby effectively improving the reflectivity of the panel, and solving the problem of low reflectivity generated under a situation that the spacing between LED light chip is less than 3 mm without reflectors.

Third, the LED light-emitting chips of the present invention are embedded in grooves, thus most of the light emitted by LED light-emitting chips enters the fixing part located above, so that the light-emitting efficiency is improved.

Fourth, the adhesive layer of the present invention may be scraped into all the grooves through the scraping process, which is simple and efficient to reduce processing time, by comparison with the prior art of using one-by-one dispensing process.

Fifth, in the invention, the hot melt adhesive is introduced to support the fixing part to avoid collision and damage to LED light-emitting chip during alignment adjustment of the fixing part. After the alignment is completed, the hot melt adhesive is melted by heating process, so that grooves of the fixing part and LED light-emitting chips are pressed together under the action of gravity, thereby greatly reducing the complexity of the process and process risk.

### BRIEF DESCRIPTION OF THE DRAWINGS

The accompanying drawings facilitate an understanding of the various embodiments of this invention. In such drawings:

FIG. 1 is a schematic diagram of a LCD system in the prior art;

FIG. 2 is a schematic diagram of a mini-LED light board in the prior art;

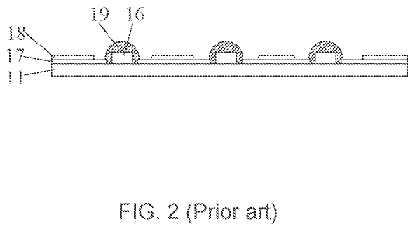

FIG. 3 is a schematic diagram of an LED light board according to an embodiment of the present invention; and

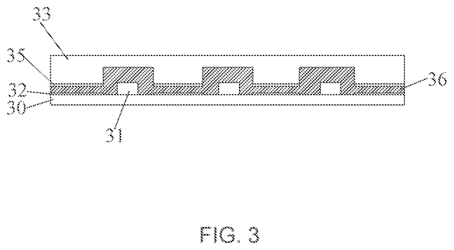

FIG. 4 is a flowchart of a manufacturing method of an LED light board according to an embodiment of the present invention.

### DETAILED DESCRIPTION OF ILLUSTRATED EMBODIMENTS

In order to make the purpose, technical solutions and advantages of the present application more clearly understood, the present application will be described in further detail below with reference to the accompanying drawings and embodiments.

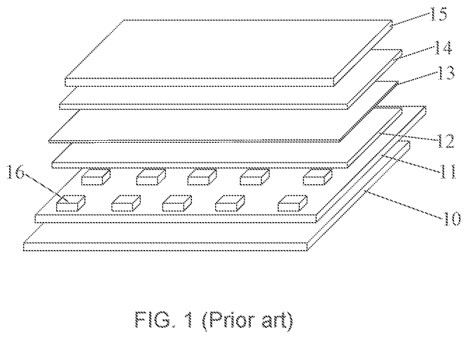

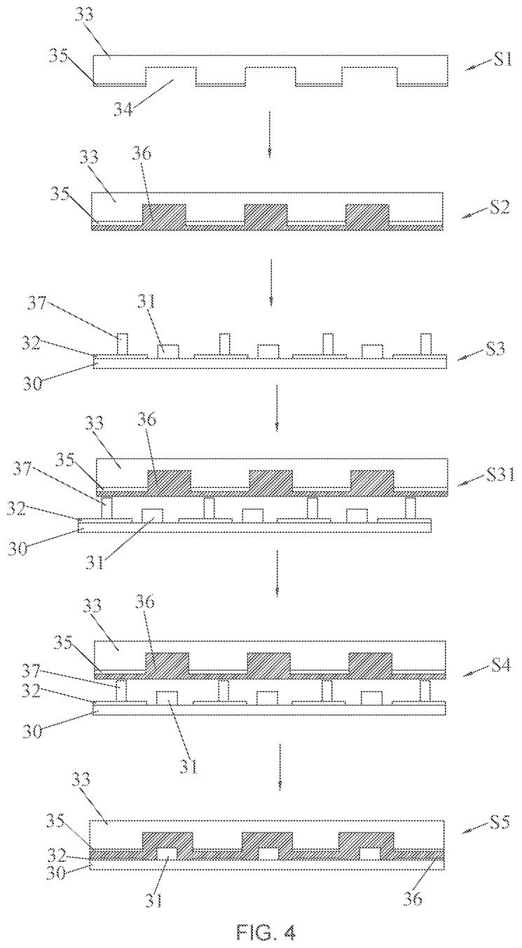

Referring to FIG. 1, the present invention provides an LED light board including a light board body 30, a fixing part 33 that is transparent and an adhesive layer 36 that is transparent. A surface of the light board body 30 is provided with a plurality of LED light-emitting chips 31 at intervals, a region of the surface of the light board body 30 without the LED light-emitting chips 31 configured is provided with a first reflecting layer 32. The fixing part 33 has a bottom side faced towards the light board body 31, the bottom side is provided with a plurality of grooves 34 (referring to FIG. 4) corresponding to each of the LED light-emitting chips 31, a region of the bottom side of the fixing part 33 without the grooves 34 configured is provided with a second reflecting layer 35. The fixing part 33 is fixedly connected with the light board body 30 by the adhesive layer 36, the fixing part 33 is located above the light board body 30, and each of the LED light-emitting chips 31 are matched with each of the grooves 34.

Specifically, the light board body 30 may be made of polymer, and preferably may be made of glass material. Multiple LED light-emitting chips 31 are arranged on the surface of the light board body 30, and the LED light-emitting chips 31 are combined into a surface light source. In a preferable embodiment, the LED light-emitting chips are arranged in a dot matrix and configured on the surface of the light board body 30. In some embodiments, the spacing between adjacent LED light-emitting chips 31 is less than 3 mm, in order to increase the number of LED light-emitting chips 31 on the light board body 30 in the unit area, thereby improving the display effect.

It should be understood that, the fixing part 33 is a transparent structure with a certain light transmittance, preferably with a light transmittance of more than 95%, and more preferably with a light transmittance of more than 99%. In a preferable embodiment, the fixing part 33 is selected from glass material or polymer optical material, and the polymer optical material is selected from at least one of PMMA, PS, or PET. The fixing part 33 is preferably made of glass material, and the grooves 34 configured on the fixing part 33 may be formed by chemical etching, which facilitates to reduce the diameter of grooves 34, in such a way, the area of the first reflecting layer 32 and the second reflecting layer 35 can be increased, thereby effectively improving the reflectivity of the panel, and solving the problem of low reflectivity generated under a case that the spacing between LED light chip 31 is less than 3 mm without reflectors. It should be understood that, the size of grooves 34 is larger than that of LED light-emitting chip 31, and preferably the grooves 34 are sized to facilitate the LED light-emitting chips 31 to be embedded in grooves 34 without any damage, which may be configured according to the actual needs. As such, each LED light-emitting chip 31 is embedded in each corresponding groove 34 in the present invention, thus most of the light emitted by LED light-emitting chips 31 enters the fixing part 33 located above, so that the light-emitting efficiency is improved.

It should be understood that, the reflectivity of the first reflecting layer 32 and the second reflecting layer 35 is preferably above 80%, above 85%, and above 90% and above 92%, more preferably. In a preferable embodiment, the first reflecting layer 32 and the second reflecting layer 35 may use, but not be limited to, reflective inks. The second reflecting layer 35 is configured on the fixing part 33, thus the second reflecting layer 35 will not go through reflow welding process with the LED light chip 31, and accordingly, there is no reflectivity loss on the second reflecting layer 35, which greatly improves the reflectivity of the panel. In a preferable embodiment, the thickness of the second reflecting layer 35 is more than 20 microns. Preferably, the thickness of the second reflecting layer 35 is more than 30 microns, which greatly improves its reflectivity.

It should be understood that, the adhesive layer 36 has a transparent structure with a certain light transmittance; preferably the light transmittance is more than 85% or 90%, and more preferably more than 95%, and even more than 99%. Specifically, the adhesive layer 36 is filled in the grooves 34 and coated on the surface of the second reflecting layer 35. The adhesive layer 36 may be heat cured or light cured so that the fixing part 33 may be fixedly connected with the light board body 30. The adhesive layer 36 may be scraped into all the grooves 34 through the scraping process, which is simple and efficient to reduce processing time, by comparison with the prior art of using one-by-one dispensing process. In some embodiments, it is preferred to use hot curing glue as the adhesive layer 36, and a hot curing temperature of over 120° C. is preferably applied, which is not limited here. In a preferable embodiment, the adhesive layer 36 is selected from silicone material or UV adhesive.

Referring to FIG. 4, The present invention further provides a manufacturing method of an LED light board, including the following steps:
S1, providing a fixing part 33, wherein a side of the fixing part 33 is provided with a plurality of grooves 34, a region of the side of the fixing part 33 without the grooves 34 configured is provided with a second reflecting layer 35;
S2, providing an adhesive layer 36 in the grooves 34 and on a surface of the second reflecting layer 35;
S3, providing a light board body 30, wherein a surface of the light board body 30 is provided with a plurality of LED light-emitting chips 31 at intervals, a region of the surface of the light board body 30 without the LED light-emitting chips 31 configured is provided with a first reflecting layer 32, and the first reflecting layer 32 is coating a hot melt adhesive 37;
S4, fitting the fixing part 33 on the light board body 30, so that each of the grooves 34 corresponds to each of the LED light-emitting chips 31;
S5, heating and melting the hot melt adhesive 37, and pressing the fixing part 33 to the light board body 30 under an action of gravity; and the placing in an oven and curing the adhesive layer 36 to obtain an LED light board.

It should be understood that, a step S31 may be included between S3 and S4. The position of the fixing part 33 may be adjusted as required so that the position of each groove 34 aligns to each LED light-emitting chip 31 of the light board body 30.

It should be understood that, the hot melt adhesive 37 is solid at room temperature and will become a molten liquid under a temperature of 50-60° C. In the invention, the hot melt adhesive 37 is introduced to support the fixing part 33 to avoid collision and damage to LED light-emitting chip 31 during alignment adjustment of the fixing part 33. After the alignment is completed, the hot melt adhesive 37 is melted by heating process, so that the grooves 34 of the fixing part 33 and LED light-emitting chips 31 are pressed together under the action of gravity, thereby greatly reducing the complexity of the process and process risk.

The manufacturing method of the LED light board of the invention is described in detail in combination with FIG. 4 and Embodiment 1 below, but the protection scope of the invention should not be limited accordingly.

### Embodiment 1

A manufacturing method of the LED light board includes the following steps:
S1, providing a fixing part 33 that is made of glass material, wherein a surface of the fixing part 33 is formed with grooves 34 by chemical etching, and the region of the surface of the fixing part 33 without the grooves 34 configured is printed with reflective inks 35 with thickness of 30 microns and reflectivity of 92%;
S2, scraping silicone into the grooves 34, filing glues into the grooves 34, and coating the silicone on the reflective inks 35, wherein the curing temperature of silicone is 120° C.;
S3, providing a light board body 30 that is made of glass material, wherein a surface of the light board body 30 is provided with a plurality of LED light-emitting chips 31 in a dot matrix to form a surface light source, the region of the surface of the light board body 30 without the LED light-emitting chips 31 configured is printed with reflective inks, and a hot melt adhesive 37 is dispensed on the reflective inks of the light board body the for support;
S31, adjusting the position of fixing part 33 to align the grooves 34 to the LED light chips 31;
S4, fitting the fixing part 33 on the light board body 30; and
S5, heating to over 50° C. to melt the hot melt adhesive 37, and pressing the fixing part 33 to the light board body 30 under an action of gravity, so that the LED light-emitting chips 31 are embedded in the grooves 34.

After connecting the fixing part 33 and the light board body 30, it is placed in the oven under heating temperature of 120° C. to cure the silicone to obtain an LED light board.

The above-mentioned embodiments only denote several embodiments of the present application, and the descriptions thereof are relatively specific and detailed, but should not be construed as limiting the scope of the patent application. It should be pointed out that for those skilled in the art, several modifications and improvements can be made without departing from the concept of the present application, which all belong to the protection scope of the present application. Therefore, the scope of protection of the patent of the present application shall be subject to the appended claims.

What is claimed is:

1. An LED light board, comprising:
a light board body, wherein a surface of the light board body is provided with a plurality of LED light-emitting chips at intervals, and a region of the surface of the light board body without the LED light-emitting chips configured is provided with a first reflecting layer;
a fixing part, wherein the fixing part is transparent and has a bottom side faced towards the light board body, the bottom side is provided with a plurality of grooves corresponding to each of the LED light-emitting chips, and a region of the bottom side of the fixing part without the grooves configured is provided with a second reflecting layer; and
an adhesive layer, wherein the adhesive layer is transparent, the fixing part is fixedly connected with the light board body by the adhesive layer, the fixing part is located above the light board body, and each of the LED light-emitting chips are matched with each of the grooves.

2. The LED light board according to claim 1, wherein the LED light-emitting chips arranged in a dot matrix are configured on the surface of the light board body.

3. The LED light board according to claim 1, wherein the first reflecting layer and the second reflecting layer comprise reflective inks.

4. The LED light board according to claim 1, wherein the fixing part is made of glass material or polymer optical material.

5. The LED light board according to claim 1, wherein the polymer optical material is selected from at least one of PMMA, PS and PET.

6. The LED light board according to claim 1, wherein the adhesive layer comprises silicone material or UV adhesive.

7. A manufacturing method of an LED light board according to claim 1, comprising:
(1) providing a fixing part, wherein a side of the fixing part is provided with a plurality of grooves, a region of the side of the fixing part without the grooves configured is provided with a second reflecting layer;
(2) providing an adhesive layer in the grooves and on a surface of the second reflecting layer;
(3) providing a light board body, wherein a surface of the light board body is provided with a plurality of LED light-emitting chips at intervals, a region of the surface of the light board body without the LED light-emitting chips configured is provided with a first reflecting layer, and the first reflecting layer is coating a hot melt adhesive;
(4) fitting the fixing part on the light board body, so that each of the grooves corresponds to each of the LED light-emitting chips;
(5) heating and melting the hot melt adhesive, and pressing the fixing part to the light board body under an action of gravity; and
(6) placing in an oven and curing the adhesive layer to obtain an LED light board.
